(19) United States
(12) Patent Application Publication
(10) Pub. No.: US 2025/0234502 A1
(43) Pub. Date: Jul. 17, 2025

(54) SEMICONDUCTOR DEVICES INCLUDING CONTACT PLUG AND METHOD OF MANUFACTURING THE SAME

(71) Applicant: Samsung Electronics Co., Ltd., Suwon-si (KR)

(72) Inventors: Seongkeun Cho, Suwon-si (KR); Songyun Kang, Suwon-si (KR); Youngrok Kwon, Suwon-si (KR); Youngseok Kim, Suwon-si (KR); Yihwan Kim, Suwon-si (KR); Kisoo Park, Suwon-si (KR); Kyeongmin Cho, Suwon-si (KR); Suhwan Hwang, Suwon-si (KR)

(21) Appl. No.: 18/947,978

(22) Filed: Nov. 14, 2024

(30) Foreign Application Priority Data
Jan. 11, 2024 (KR) 10-2024-0004636

(51) Int. Cl. H10B 12/00

(52) U.S. Cl. CPC H10B 12/0335; H10B 12/05

(57) ABSTRACT

A semiconductor device manufacturing method includes forming a cell gate structure in a substrate comprising a cell area and a peripheral circuit area; forming bit line structures on the cell area; forming a peripheral structure comprising a peripheral gate structure on the peripheral circuit area; forming a semiconductor material layer covering the bit line structures and the peripheral structure; and forming a contact plug between the bit line structures by laser annealing the semiconductor material layer using a laser beam. Forming the contact plug includes crystallizing an upper portion of the semiconductor material layer by performing a primary laser annealing process to form a first preliminary crystal layer; crystallizing a lower portion of the semiconductor material layer by performing a secondary laser annealing process to form a second crystal layer; and removing an upper portion of the first preliminary crystal layer to form a first crystal layer.

### CROSS-REFERENCE TO RELATED APPLICATION(S)

This application claims the benefit of priority under 35 U.S.C. § 119 to Korean Patent Application No. 10-2024-0004636 filed on Jan. 11, 2024 in the Korean Intellectual Property Office, the disclosure of which is incorporated herein by reference in its entirety.

### BACKGROUND

Aspects of the present inventive concept relate to a semiconductor device including a contact plug and a method of manufacturing the same.

As demand for high performance, high speed, and/or multifunctionality of a semiconductor device has increased, integration density of semiconductor devices has increased. In manufacturing a semiconductor device having a fine pattern corresponding to the trend for high integration density of semiconductor devices, it may be necessary to implement patterns having a fine width or a fine spacing distance.

### SUMMARY

It is an object of the present inventive concept to provide a semiconductor device including a contact plug having a plurality of crystal layers and a method of manufacturing the same.

According to an aspect of the present inventive concept, a method of manufacturing a semiconductor device includes: forming a cell gate structure in a substrate comprising a cell area and a peripheral circuit area; forming bit line structures on the cell area; forming a peripheral structure comprising a peripheral gate structure on the peripheral circuit area; forming a semiconductor material layer covering the bit line structures and the peripheral structure; and forming a contact plug between the bit line structures by laser annealing the semiconductor material layer using a laser beam, wherein the forming the contact plug comprises: crystallizing an upper portion of the semiconductor material layer by performing a primary laser annealing process to form a first preliminary crystal layer; crystallizing a lower portion of the semiconductor material layer by performing a secondary laser annealing process to form a second crystal layer; and removing an upper portion of the first preliminary crystal layer to form a first crystal layer.

According to an aspect of the present inventive concept, a method of manufacturing a semiconductor device includes: forming a cell gate structure in a substrate comprising a cell area and a peripheral circuit area; forming bit line structures on the cell area; forming a peripheral structure comprising a peripheral gate structure on the peripheral circuit area; forming a semiconductor material layer covering the bit line structures and the peripheral structure; and forming a contact plug between the bit line structures by laser annealing the semiconductor material layer using a laser beam, wherein the forming the contact plug comprises crystallizing the semiconductor material layer by M laser annealing processes, where M is 2 or more, and at least two of respective laser beams used for the M laser annealing processes have different energy densities to each other.

According to an aspect of the present inventive concept, a semiconductor device includes: a substrate comprising an active region including a first impurity region and a second impurity region; a gate structure disposed within the substrate and intersecting the active region;

bit line structures electrically connected to the first impurity region intersecting the gate structure; a contact plug disposed between the bit line structures and electrically connected to the second impurity region; a landing pad on the contact plug; and a capacitor structure on the landing pad, wherein the contact plug comprises a plurality of crystal layers stacked in a vertical direction, the plurality of crystal layers comprise a first crystal layer and a second crystal layer, below the first crystal layer, and a grain size of the first crystal layer is different from a grain size of the second crystal layer.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a plan view of a semiconductor device according to an exemplary embodiment;

FIG. 2 is an enlarged view of a portion of the semiconductor device illustrated in FIG. 1;

FIG. 3 is a vertical cross-sectional view taken along line I-I′ of the semiconductor device illustrated in FIG. 2;

FIG. 4 is a vertical cross-sectional view taken along line II-II′ of the semiconductor device illustrated in FIG. 2;

FIG. 5 is an enlarged view of a portion of the semiconductor device illustrated in FIG. 3;

FIGS. 6A and 6B are vertical cross-sectional views of a semiconductor device according to an exemplary embodiment;

FIG. 7A is a flow chart of a method of manufacturing a semiconductor device according to an exemplary embodiment;

FIG. 7B is a flow chart of a method of forming a contact plug according to an exemplary embodiment;

FIGS. 8A, 8B, 9A, 9B, 10A, 10B, 11A, 11B, 12A, 12B and 13 to 15 are vertical cross-sectional views illustrated according to a process sequence to explain a method of manufacturing a semiconductor device according to an exemplary embodiment;

FIG. 16 illustrates a laser annealing energy as a function of a spacing between bit lines;

FIG. 17 illustrates a reflectance as a function of a thickness of a semiconductor material layer;

FIG. 18A illustrates a reflectance of a laser beam in a cell area and a peripheral circuit area according to a comparative example;

FIG. 18B illustrates a reflectance of a laser beam in a cell area and a peripheral circuit area according to an embodiment;

FIG. 19 illustrates an extinction coefficient as a function of a crystal state of silicon and a wavelength;

FIG. 20A illustrates a temperature of a semiconductor material layer on a cell area according to a comparative example;

FIG. 20B illustrates a temperature of a semiconductor material layer on a cell area according to an embodiment;

FIG. 21A illustrates a temperature of a semiconductor material layer on a cell area according to a comparative example;

FIG. 21B illustrates a temperature of a semiconductor material layer on a cell area according to an embodiment; and

FIG. 22 illustrates a reflectance as a function of a thickness of a first preliminary crystal layer during a secondary laser annealing process.

### DETAILED DESCRIPTION

Hereinafter, exemplary embodiments of the present inventive concept will be described with reference to the accompanying drawings.

Throughout the specification, when a component is described as “including” a particular element or group of elements, it is to be understood that the component is formed of only the element or the group of elements, or the element or group of elements may be combined with additional elements to form the component, unless the context clearly and/or explicitly describes the contrary. The term “consisting of,” on the other hand, indicates that a component is formed only of the element(s) listed.

Terms such as “about” or “approximately” may reflect amounts, sizes, orientations, or layouts that vary only in a small relative manner, and/or in a way that does not significantly alter the operation, functionality, or structure of certain elements. For example, a range from “about 0.1 to about 1” may encompass a range such as a 0%-5% deviation around 0.1 and a 0% to 5% deviation around 1, especially if such deviation maintains the same effect as the listed range.

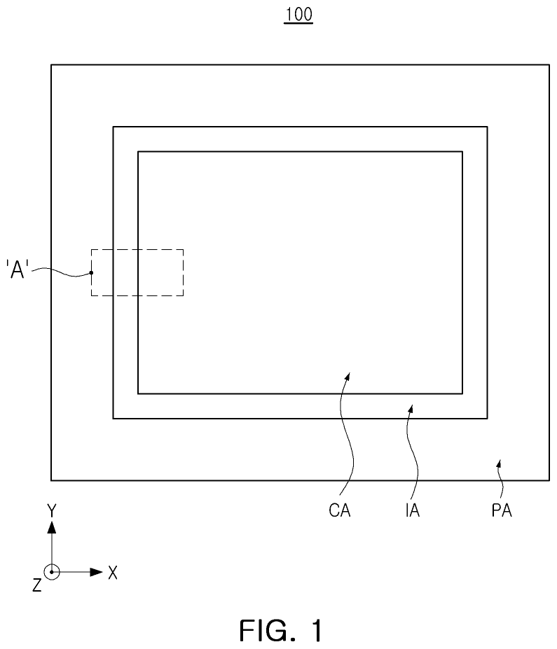

FIG. 1 is a plan view illustrating a semiconductor device according to an exemplary embodiment.

Referring to FIG. 1, a semiconductor device 100 according to an exemplary embodiment of the present inventive concept may include a cell area CA, an interface area IA, and a peripheral circuit area PA. The peripheral circuit area PA may be disposed to surround the cell area CA, and the interface area IA may be disposed between the cell area CA and the peripheral circuit area PA. The cell area CA may refer to a region in which memory cells of a dynamic random access memory (DRAM) device are disposed, and the peripheral circuit area PA may be a region in which word line drivers, sense amplifiers, row and column decoders, and control circuits are disposed. The interface area IA may be a region for electrically connecting the cell area CA to the peripheral circuit area PA.

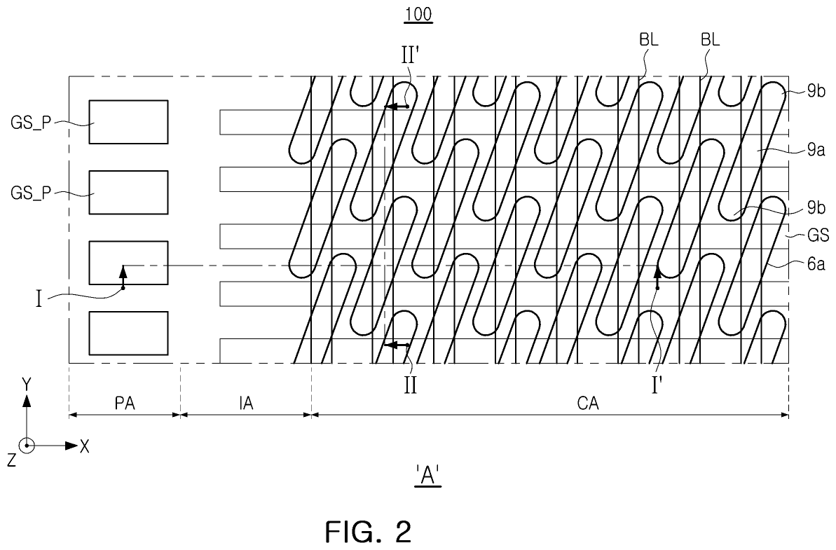

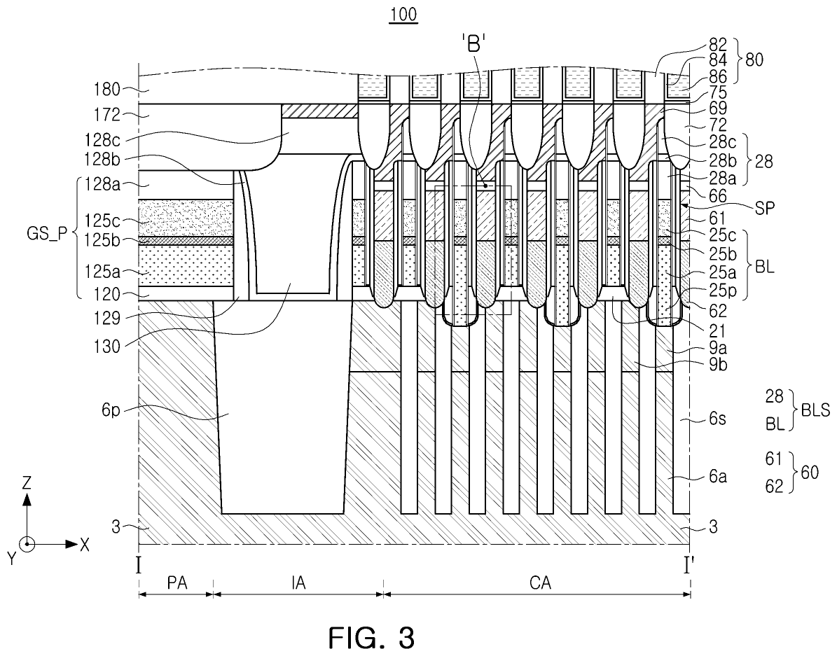

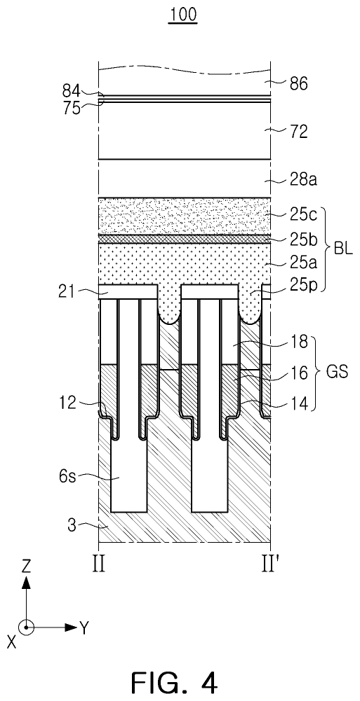

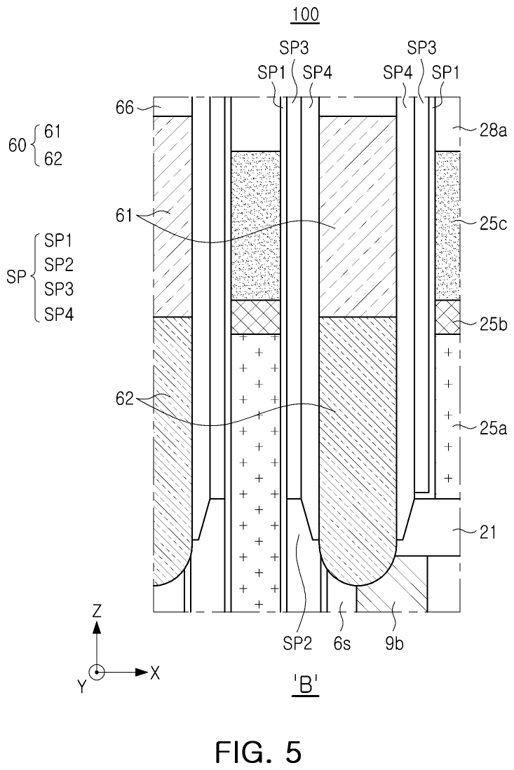

FIG. 2 is an enlarged view of a portion of the semiconductor device illustrated in FIG. 1, corresponding to region A of FIG. 1. FIG. 3 is a vertical cross-sectional view taken along line I-I′ of the semiconductor device illustrated in FIG. 2. FIG. 4 is a vertical cross-sectional view taken along line II-II′ of the semiconductor device illustrated in FIG. 2. FIG. 5 is an enlarged view of a portion of the semiconductor device illustrated in FIG. 3, corresponding to region B of FIG. 1.

Referring to FIGS. 2 to 5, the semiconductor device 100 according to an embodiment of the present inventive concept may include cell gate structure GS disposed in a substrate 3 in the cell area CA, a buffer layer 21, a bitline structure BLS, a spacer structure SP, a contact plug 60, a landing pad 69, a cell insulating pattern 72 and a capacitor structure 80 disposed on the substrate 3. For example, the semiconductor device 100 may be applied to a cell array of a dynamic random access memory (DRAM), but the present inventive concept is not limited thereto.

The semiconductor device 100 may further include a peripheral gate structure GS_P disposed on the substrate 3, a lower interlayer insulating layer 130, a peripheral insulating pattern 172 and an upper interlayer insulating layer 180 in the peripheral circuit area PA.

The substrate 3 may include a semiconductor material, such as a group IV semiconductor, a group III-V compound semiconductor, or a group II-VI compound semiconductor. For example, the group IV semiconductor may include silicon, germanium, or silicon-germanium. The substrate 3 may be a silicon substrate, a silicon on insulator (SOI) substrate, a germanium substrate, a germanium on insulator (GOI) substrate, a silicon-germanium substrate, or a substrate including an epitaxial layer.

In the cell area CA, the substrate 3 may include an active region 6a, a first device isolation layer 6s, a first impurity region 9a, and a second impurity region 9b. The first device isolation layer 6s may be configured as an insulating layer extending downward from an upper surface of the substrate 3 and may define the active region 6a. For example, the active region 6a may correspond to a portion of the upper surface of the substrate 3 surrounded by the first device isolation layer 6s. When viewed in a plan view, the first active region 6a may have a bar shape having a minor axis and a major axis, and may extend in a direction inclined to the X-direction and Y-direction. The first device isolation layer 6s may include silicon oxide, silicon nitride, silicon oxynitride, or a combination thereof, and may be made of a single layer or a plurality of layers.

The active region 6a may include first and second impurity regions 9a and 9b extending to a predetermined depth from the upper surface of the substrate 3. The first and second impurity regions 9a and 9b may be spaced apart from each other. The first and second impurity regions 9a and 9b may be provided as a source or drain region of a transistor. For example, for a single active region 6a, two cell gate structures GS may intersect the single active region 6a, and a drain region may be formed between the two cell gate structures GS, and source regions may be formed in regions opposite to the regions for the two cell gate structures GS. For example, the first impurity region 9a may correspond to the drain region, and the second impurity region 9b may correspond to the source region. The source region and the drain region may be formed by the first and second impurity regions 9a and 9b by doping or ion implantation of substantially the same impurities, and may be referred to interchangeably depending on a circuit configuration of a finally formed transistor. The first and second impurity regions 9a and 9b may include impurities having a conductivity-type opposite to that of the substrate 3. For example, the active regions 6a, may include P-type impurities, and the first and second impurity regions 9a and 9b may include N-type impurities.

In the cell area CA, the cell gate structures GS may extend in the X-direction and may be spaced apart from each other in the Y-direction. In addition, the cell gate structures GS may intersect the active region 6a. For example, two cell gate structures GS may intersect the single active region 6a. Transistors each including the cell gate structure GS and the first and second impurity regions 9a and 9b may constitute a buried channel array transistor (BCAT), but the present inventive concept is not limited thereto.

When viewed in a cross-sectional view, the cell gate structures GS may be embedded in the substrate 3. For example, the cell gate structures GS may be disposed in a gate trench 12 formed in the substrate 3. The cell gate structure GS may include a gate dielectric layer 14, a gate electrode 16 and a gate capping layer 18 disposed in the gate trench 12. The gate dielectric layer 14 may be conformally formed on an internal wall of the gate trench 12. The gate electrode 16 may be disposed on a lower portion of the gate trench 12, and a gate capping layer 18 may be disposed on an upper portion of the cell gate structure GS and may fill the gate trench 12.

The cell gate dielectric layer 14 may include silicon oxide or a material having a high dielectric constant. In exemplary embodiments, the cell gate dielectric layer 14 may be formed by oxidizing the first active region 6a or may be formed by deposition. The gate electrode 16 may include a conductive material, for example, polycrystalline silicon (Si), titanium (Ti), titanium nitride (TiN), tantalum (Ta), tantalum nitride (TaN), tungsten (W), tungsten nitride (WN), and aluminum (Al). The gate capping layer 18 may include silicon nitride.

In the cell area CA, the buffer layer 21 may be disposed on the active region 6a, the first device isolation layer 6s, and the cell gate structure GS. The buffer layer 21 may include silicon oxide, silicon nitride, silicon oxynitride, or a combination thereof. The buffer layer 21 may be configured as a single layer or a plurality of layers.

In the cell area CA, the bitline structures BLS may extend in the Y-direction and may be spaced apart from each other in the X-direction. The bitline structure BLS may have a bar shape extending in the Y-direction. The bitline structure BLS may include a bitline BL and a bitline capping layer 28 on the bitline BL. The bitline BL may include a first conductive layer 25a, a second conductive layer 25b and a third conductive layer 25c that are sequentially stacked on the buffer layer 21. The first conductive layer 25a may include polysilicon. The second conductive layer 25b may include a metal-semiconductor compound. The metal-semiconductor compound may be obtained by, for example, siliciding a portion of the first conductive layer 25a. For example, the metal-semiconductor compound may include cobalt silicide (CoSi), titanium silicide (TiSi), nickel silicide (NiSi), tungsten silicide (WSi), or other metal silicides, or may include nitrides such as TiSiN. The third conductive layer 25c may include a metal material such as titanium (Ti), tantalum (Ta), tungsten (W), and aluminum (Al). The bitline BL may further include a plug portion 25p disposed below the first conductive layer 25a, extending downward and in contact with the second impurity region 9b. The plug portion 25p may be positioned in a contact hole formed on the upper surface of the substrate 3. When viewed in a plan view, the plug portion 25p may be in contact with a central portion of the active region 6a. The plug portion 25p may electrically connect the active region 6a to the bitline structure BLS. The plug portion 25p may include the same material as that of the first conductive layer 25a.

The bitline capping layer 28 may include a first capping layer 28a, a second capping layer 28b, and a third capping layer 28c that at are sequentially stacked on the bit line BL. A side surface of the first capping layer 28a may be coplanar with the first conductive layer 25a, the second conductive layer 25b, and the third conductive layer 25c. The first capping layer 28a, the second capping layer 28b and the third capping layer 28c may include silicon oxide, silicon nitride, silicon oxynitride, or a combination thereof, and may include, for example, silicon nitride.

A spacer structure SP may be disposed on either side surface of the bitline structures BLS, and may extend in the Y-direction along the side surfaces of the bitline structures BLS. The spacer structure SP may include a first spacer SP1, a second spacer SP2, a third spacer SP3, and a fourth spacer SP4 disposed on the side surface of the bitline structure BLS. The first spacer SP1 may be conformally disposed along the side surfaces of the bitline structure BLS and the contact hole H. The second spacer SP2 may be disposed on the first spacer SP1 and may fill the contact hole H. The third spacer SP3 may cover a side surface of the first spacer SP1, and the fourth spacer SP4 may cover a side surface of the third spacer SP3. The third spacer SP3 and the fourth spacer SP4 may cover an upper surface of the second spacer SP2. The first spacer SP1, the second spacer SP2, the third spacer SP3, and the fourth spacer SP4 may each include silicon oxide, silicon nitride, silicon oxynitride, or a combination thereof. For example, the first spacer SP1 and the fourth spacer SP4 may include at least one of SiN, SiCN, SiON, and SiOCN. The third spacer SP3 may include silicon oxide. However, the structure and material of the spacer structure SP illustrated in FIG. 3 are illustrative, and aspects of the present inventive concept are not limited thereto.

The contact plug 60 is disposed between the bit line structures BLS and may be in contact with the spacer structures SP. When viewed in a plan view, the contact plugs 60 may be disposed between the bitline structures BLS and between the cell gate structures GS. The contact plug 60 may extend into the substrate 3 to be in contact with the second impurity region 9b of the active region 6a and may be electrically connected to the second impurity region 9b.

In an embodiment, the contact plug 60 may consist of a plurality of layers. For example, the contact plug 60 may include a first crystal layer 61 and a second crystal layer 62 below the first crystal layer 61. A lower end of the second crystal layer 62 may be located at a level lower than the upper surface of the substrate 3, and an upper surface of the first crystal layer 61 may be located at a level lower than an upper end of the bit line structure BLS. The contact plug 60 may be made of a conductive material, and may include at least one of polysilicon (Si), titanium (Ti), titanium nitride (TiN), tantalum (Ta), tantalum nitride (TaN), tungsten (W), tungsten nitride (WN), and aluminum (Al), for example. In an embodiment, the contact plug 60 may include doped polysilicon, and may include N-type impurities such as phosphorus (P), arsenic (As) and antimony (Sb). The first crystal layer 61 may include the same material as the second crystal layer 62.

In an embodiment, an interface may be observed between the first crystal layer 61 and the second crystal layer 62. For example, an average grain size of the first crystal layer 61 may be different from an average grain size of the second crystal layer 62. In an embodiment, an average grain size of the first crystal layer 61 may be greater than an average grain size of the second crystal layer 62. In an embodiment, an extinction coefficient of the first crystal layer 61 may be different from that of the second crystal layer 62. For example, an extinction coefficient of the first crystal layer 61 may be less than that of the second crystal layer 62.

The semiconductor device 100 may further include a fence structure disposed between the bitline structures BLS. When viewed in a plan view, the fence structures may overlap the cell gate structures GS in a vertical direction, and may be alternately disposed with the contact plugs 60 in the Y-direction. The fence structures may spatially isolate the contact plugs 60 from each other and may electrically insulate the contact plugs 60 from each other. The fence structure may include an insulating material, for example, silicon nitride.

The semiconductor device 100 may further include a metal-semiconductor compound layer 66 disposed on an upper surface of the contact plug 60. The metal-semiconductor compound layer 66 may be in contact with a side surface of the spacer structure SP. The metal-semiconductor compound layer 66 may be formed by siliciding a portion of the contact plug 60 including polysilicon. The metal-semiconductor compound layer 66 may include cobalt silicide (CoSi), titanium silicide (TiSi), nickel silicide (NiSi), tungsten silicide (WSi), or other metal silicide.

A landing pad 69 may be disposed on the metal-semiconductor compound layer 66. The landing pad 69 may be electrically connected to the second impurity region 9b of the active region 6a through the contact plug 60. The landing pad 69 may include a barrier layer and a metal layer on the barrier layer. The barrier layer may include at least one of metal nitrides, such as titanium nitride (TiN), tantalum nitride (TaN), tungsten nitride (WN), molybdenum nitride (MoN), ruthenium nitride (RuN), and aluminum nitride (AlN). The metal layer may include at least one of titanium (Ti), tantalum (Ta), tungsten (W), molybdenum (Mo), ruthenium (Ru) and aluminum (Al). For example, the metal layer may include tungsten (W).

In the cell area CA, the cell insulating pattern 72 may be disposed between the landing pads 69. The cell insulating pattern 72 may spatially isolate the landing pads 69 from each other and may electrically insulate the landing pads 69 from each other. The cell insulating pattern 72 may be in contact with the bit line structure BLS, the spacer structure SP and the landing pads 69.

The cell insulating pattern 72 may include silicon oxide, silicon nitride, silicon oxynitride or a combination thereof. For example, the cell insulating pattern 72 may include silicon nitride.

In the cell area CA, the semiconductor device 100 may further include an etch stop layer 75 covering an upper surface of the insulating pattern structure 72. The capacitor structure 80 may be disposed on the landing pad 69 and the cell insulating pattern 72. The capacitor structure 80 may include a lower electrode 82, a capacitor dielectric layer 84 and an upper electrode 86. The lower electrode 82 may penetrate through the etch stop layer 75 and may be in contact with an upper surface of the landing pad 69. The capacitor dielectric layer 84 may cover the lower electrode 82 and the etch stop layer 75, and the upper electrode 86 may cover the capacitor dielectric layer 84. The capacitor structure 80 may be electrically connected to the landing pad 69 and the contact plug 60.

The lower electrode 82 and the upper electrode 86 may include at least one of a doped semiconductor, a metal nitride, a metal and a metal oxide. The lower electrode 82 and the upper electrode 86 may include, for example, at least one of polycrystalline silicon, titanium nitride (TiN), tungsten (W), titanium (Ti), ruthenium (Ru), and tungsten nitride (WN). The capacitor dielectric layer 84 may include, for example, at least one of high dielectric constant materials such as zirconium oxide (ZrO₂), aluminum oxide (Al₂O₃), and hafnium oxide (Hf₂O₃).

In the interface area IA, the substrate 3 may further include a second device isolation layer 6p. The second device isolation layer 6p may be an insulating layer extending downward from the upper surface of the substrate 3. The second device isolation layer 6p may include silicon oxide, silicon nitride, silicon oxynitride, or a combination thereof, and may be made of a single layer or a plurality of layers.

In the peripheral circuit area PA, the peripheral gate structure GS_P may be disposed on the second active region 8. The peripheral gate structure GS_P may include a peripheral gate dielectric layer 120, a first conductive layer 125a, a second conductive layer 125b, a third conductive layer 125c and a peripheral gate capping layer 128a that are sequentially stacked on the substrate 3. The peripheral gate dielectric layer 120 may include silicon oxide, silicon nitride or a high-k material. The high-K material may refer to a dielectric material having a dielectric constant greater than that of silicon oxide. The first conductive layer 125a, the second conductive layer 125b and the third conductive layer 125c of the peripheral gate structure GS_P may include the same material as the first conductive layer 25a, the second conductive layer 25b and the third conductive layer 25c of the bitline BL, respectively. The peripheral gate capping layer 128a may include the same material as the first capping layer 28a of the bit line capping layer 28. However, the materials and structures of the first conductive layer 125a, the second conductive layer 125b, the third conductive layer 125c and the peripheral gate capping layer 128a are exemplary, and aspects of the present inventive concept are not limited thereto.

Although not shown, the substrate 3 may further include impurity regions disposed adjacent to the peripheral gate structure GS_P on the peripheral circuit area PA.

The semiconductor device 100 may further include a peripheral gate spacer 129, a first peripheral capping layer 128b, a second peripheral capping layer 128c and a lower interlayer insulating layer 130 on the peripheral circuit area PA. The peripheral gate spacer 129 may cover a side surface of the peripheral gate structure GS_P. For example, the peripheral gate spacers 129 may cover side surfaces of the first conductive layer 125a, the second conductive layer 125b, the third conductive layer 125c and the peripheral gate capping layer 128a.

The first peripheral capping layer 128b may cover the substrate 3, the peripheral gate spacer 129 and the peripheral gate structure GS_P, and may be conformally formed. The lower interlayer insulating layer 130 may partially cover the first peripheral capping layer 128b. An upper surface of the lower interlayer insulating layer 130 may be coplanar with an upper surface of the first peripheral capping layer 128b. The second peripheral capping layer 128c may cover the lower interlayer insulating layer 130 and the first peripheral capping layer 128b.

The first peripheral capping layer 128b and the second peripheral capping layer 128c may include the same material as the second capping layer 28b and the third capping layer 28c of the bit line capping layer 28, respectively, and for example, may include silicon nitride. The lower interlayer insulating layer 130 may include silicon oxide, silicon nitride, silicon oxynitride or a combination thereof, and for example, may include silicon oxide.

Although not shown, the semiconductor device 100 may further include a peripheral interconnection disposed at the same level as the landing pad 69 and a peripheral contact plug connected to the peripheral interconnection and disposed adjacent to the peripheral gate structure GS_P on the peripheral circuit area PA.

The semiconductor device 100 may further include a peripheral insulating pattern 172 and an upper interlayer insulating layer 180 disposed on the peripheral gate structure GS_P. The peripheral insulating pattern 172 may be disposed on the peripheral circuit area PA and the interface area IA, and may be in contact with the peripheral gate capping layer 128a. The peripheral insulating pattern 172 may also be in contact with the peripheral gate spacer 129, the first peripheral capping layer 128b, the lower interlayer insulating layer 130 and the second peripheral capping layer 128c. The upper interlayer insulating layer 180 may be disposed on the peripheral circuit area PA and the interface area IA, may be disposed on the peripheral insulating pattern 172, and may be disposed at the same level as the capacitor structure 80.

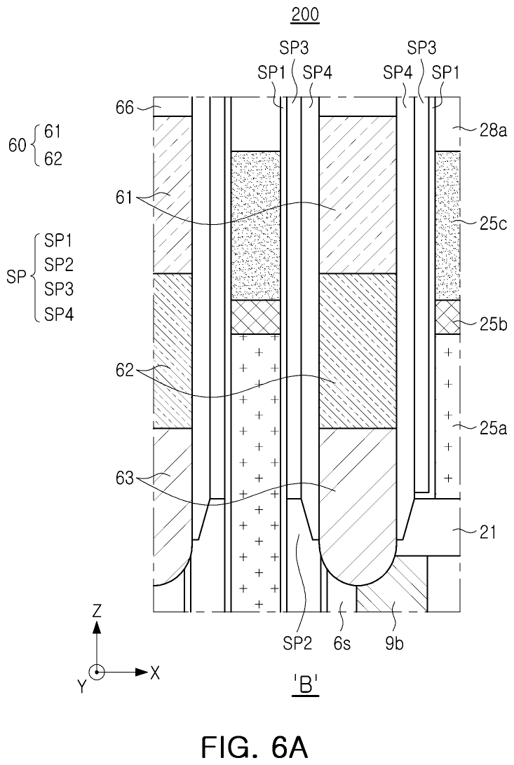

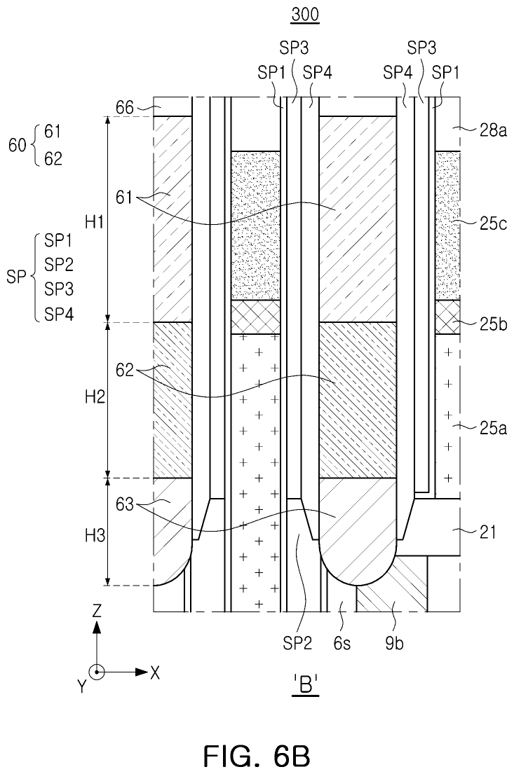

FIGS. 6A and 6B are vertical cross-sectional views of a semiconductor device according to an exemplary embodiment.

Referring to FIG. 6A, a semiconductor device 200 may include a contact plug 60 disposed between bit line structures BLS. In an embodiment, the contact plug 60 may consist of a plurality of crystal layers. For example, the contact plug 60 may include a first crystal layer 61, a second crystal layer 62 below the first crystal layer 61 and a third crystal layer 63 below the second crystal layer 62. In an embodiment, an interface may be observed between the first crystal layer 61 and the second crystal layer 62, and an interface may be observed between the second crystal layer 62 and the third crystal layer 63. For example, an average grain size of the first crystal layer 61, an average grain size of the second crystal layer 62 and an average grain size of the third crystal layer 63 may be different from each other. In an embodiment, the average grain size of the second crystal layer 62 may be greater than the average grain size of the third crystal layer 63, and may be less than the average grain size of the first crystal layer 61.

Referring to FIG. 6B, a semiconductor device 300 may include a contact plug 60 disposed between bit line structures BLS. In an embodiment, the contact plug 60 may consist of a plurality of crystal layers. For example, the contact plug 60 may include a first crystal layer 61, a second crystal layer 62 below the first crystal layer 61 and a third crystal layer 63 below the second crystal layer 62. In an embodiment, heights of the first crystal layer 61, the second crystal layer 62 and the third crystal layer 63 may be different from each other. For example, the height H2 of the second crystal layer 62 may be less than the height H1 of the first crystal layer 61, and may be greater than the height H3 of the third crystal layer 63.

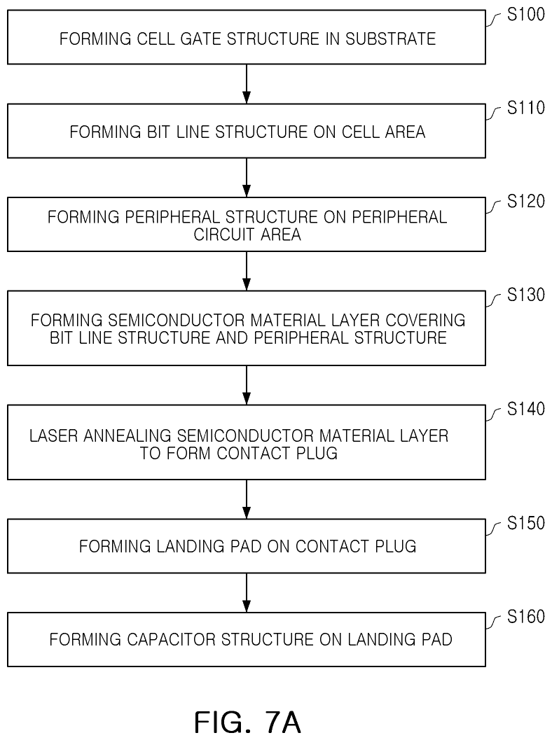

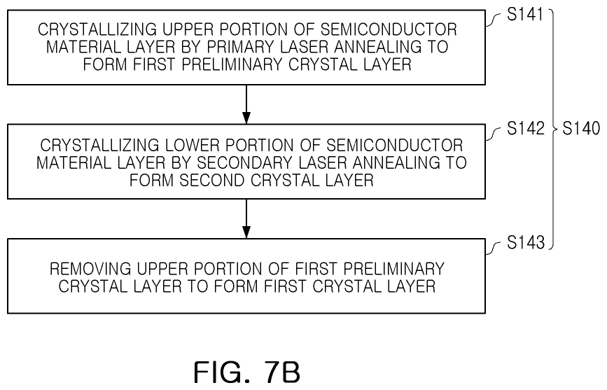

FIG. 7A is a flow chart of a method of manufacturing a semiconductor device according to an exemplary embodiment. FIG. 7B is a flow chart of a method of forming a contact plug according to an exemplary embodiment.

Referring to FIG. 7A, the method of manufacturing a semiconductor device according to an embodiment may include forming a cell gate structure (GS) in the substrate 3 (S100), forming a bit line structure BLS on the cell area CA (S110), forming a peripheral structure on a peripheral circuit area PA (S120), forming a semiconductor material layer covering the bit line structure BLS and the peripheral structure (S130), laser annealing the semiconductor material layer to form a contact plug 60 (S140), forming a landing pad 69 on the contact plug 60 (S150), and forming a capacitor structure 80 on the landing pad 69 (S160).

Referring to FIG. 7B, the laser annealing the semiconductor material layer to form a contact plug 60 (S140) may include crystallizing an upper portion of the semiconductor material layer by performing a primary laser annealing process to form a first preliminary crystal layer (S141), crystallizing a lower portion of the semiconductor material layer by performing a secondary laser annealing process to form a second crystal layer (S142), and removing an upper portion of the first preliminary crystal layer to form a first crystal layer (S143).

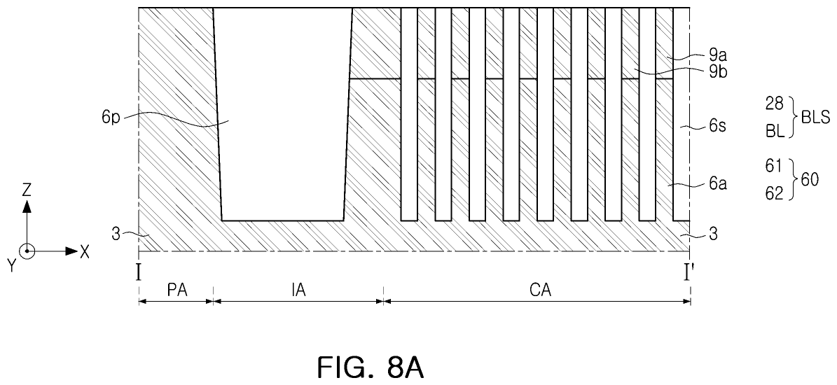

FIGS. 8A, 8B, 9A, 9B, 10A, 10B, 11A, 11B, 12A, 12B and 13 to 15 are vertical cross-sectional views illustrated according to the process sequence to explain a method of manufacturing a semiconductor device according to an exemplary embodiment. Specifically, FIGS. 8A, 9A, 10A, 11A, 12A and 13 to 15 correspond to FIG. 3 and are vertical cross-sectional views taken along line I-I′, and FIGS. 8B, 9B, 10B, 11B and 12B correspond to FIG. 4 and are vertical cross-sectional views taken along line II-II′.

Referring to FIGS. 7A, 8A and 8B, a first device isolation layer 6s may be formed in the substrate 3, and the cell gate structure GS may be formed in the substrate 3 (S100). The first device isolation layer 6s may be formed by forming a trench on an upper surface of the substrate 3, filling the trench with an insulating material, and performing a planarization process of etching the substrate 3 and the insulating material. The first device isolation layer 6s may define active regions 6a. For example, the active regions 6a may correspond to a portion of the upper surface of the substrate 3 surrounded by the first device isolation layer 6s. When viewed in a plan view, the active regions 6a may have a bar shape having minor and major axes, and may be spaced apart from each other. The first device isolation layer 6s may include a single layer or a plurality of layers.

In an embodiment, a first impurity region 9a and a second impurity region 9b may be formed by implanting impurities into the substrate 3 before the first device isolation layer 6s is formed. However, in embodiments, the first impurity region 9a and the second impurity region 9b may be formed after the first device isolation layer 6s is formed or in a different process.

Subsequently, gate trenches 12 may be formed by anisotropically etching the substrate 3. The gate trenches 12 may extend in the X-direction and may intersect the active region 6a and the first device isolation layer 6s. The cell gate structure GS may be formed by forming a cell gate dielectric layer 14, a gate electrode 16 and a gate capping layer 18 in the gate trench 12. The cell gate dielectric layer 14 may be conformally formed on an internal wall of the gate trench 12. The gate electrode 16 may be formed by forming a conductive material on the gate dielectric layer 14 and then recessing the conductive material. The gate capping layer 18 may be formed by forming an insulating material on the gate electrode 16 to fill the gate trench 12 and performing a planarization process. In an embodiment, as illustrated in FIG. 8B, the gate trench 12 may be formed to have a deeper depth in the first device isolation layer 6s than in the active region 6a.

In the peripheral circuit area PA, a second device isolation layer 6p may be formed in the substrate 3. In an embodiment, the second device isolation layer 6p may be formed simultaneously with the first device isolation layer 6s, but aspects of the present inventive concept are not limited thereto.

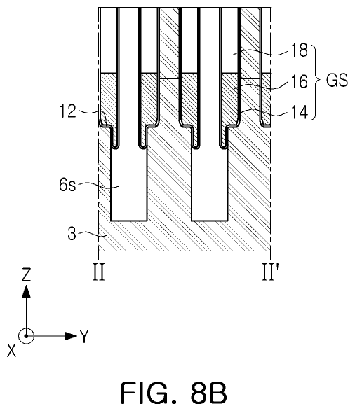

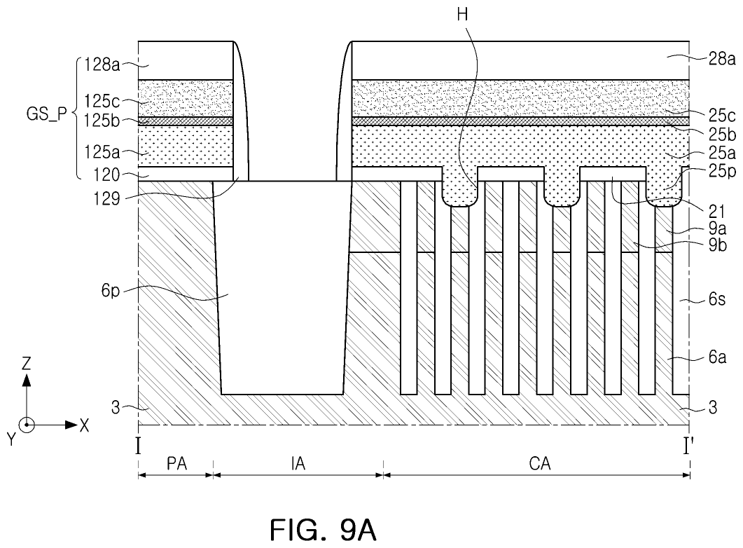

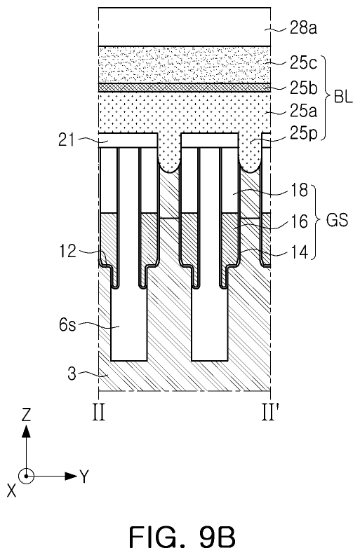

Referring to FIGS. 9A and 9B, a buffer layer 21 may be formed on the substrate 3 in the cell area CA. The buffer layer 21 may cover upper surfaces of the substrate 3, the active region 6a, the first device isolation layer 6s and the cell gate structure GS. The buffer layer 21 may consist of a single layer or a plurality of layers.

A contact hole (H) may be formed on the upper surface of the substrate 3 by etching the upper surface of the substrate 3 and the buffer layer 21. A first conductive layer 25a, a second conductive layer 25b and a third conductive layer 25c may be formed by stacking conductive material layers on the buffer layer 21 and the contact hole H. The conductive material layer that fills the inside of the contact hole (H) may be referred to as a plug portion 25p.

A peripheral gate structure GS_P may be formed on the peripheral circuit area PA. The peripheral gate structure GS_P may include a peripheral gate dielectric layer 120, a first conductive layer 125a, a second conductive layer 125b, a third conductive layer 125c and a peripheral gate capping layer 128a that are sequentially stacked. The peripheral gate structure GS_P may be formed by forming a dielectric material on the substrate 3, stacking a conductive material and an insulating material on the dielectric material, and patterning the dielectric material, the conductive material and the insulating material. In an embodiment, the first conductive layer 125a, the second conductive layer 125b and the third conductive layer 125c of the peripheral gate structure GS_P may be formed in the same process as the first conductive layer 25a, the second conductive layer 25b and the third conductive layer 25c. The first conductive layer 125a, the second conductive layer 125b and the third conductive layer 125c of the peripheral gate structure GS_P may include the same material as the first conductive layer 25a, the second conductive layer 25b and the third conductive layer 25c, respectively. In an embodiment, the peripheral gate capping layer 128a of the peripheral gate structure GS_P may be formed in the same process as the first capping layer 28a. In some embodiments, the peripheral gate structure GS_P may be formed in a different process from the process of forming the first conductive layer 25a, the second conductive layer 25b, the third conductive layer 25c and the first capping layer 28a.

After the peripheral gate structure GS_P is formed, a peripheral gate spacer 129 may be formed by depositing an insulating material covering the peripheral gate structure GS_P and anisotropically etching the insulating material. Side surfaces of the first conductive layer 25a, the second conductive layer 25b, the third conductive layer 25c, and the first capping layer 28a may also be covered by the peripheral gate spacer 129.

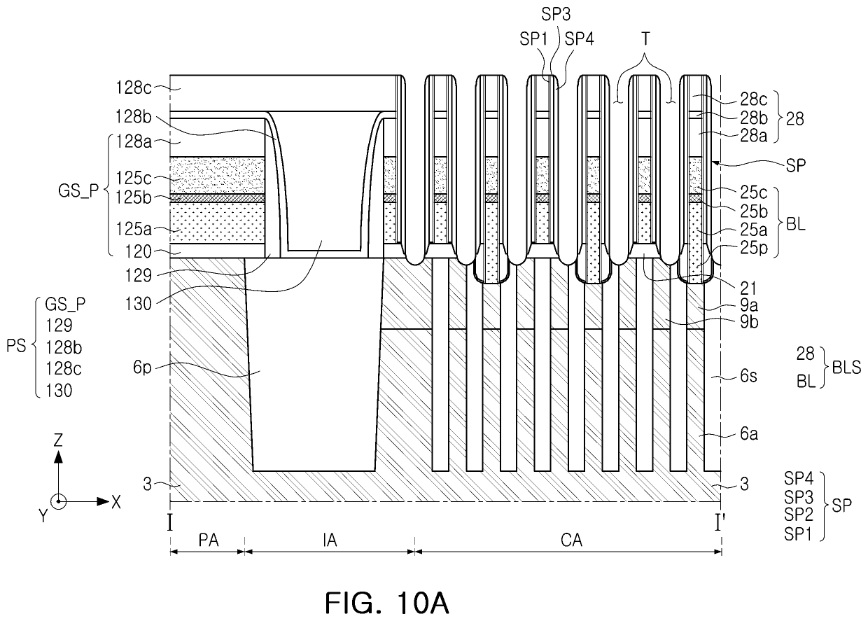

Referring to FIGS. 7A, 10A, and 10B, the bit line structure BLS may be formed on the cell area CA (S110), and the peripheral structure may be formed on the peripheral circuit area PA (S120).

After stacking insulating material layers on the first capping layer 28a, the bit line structure BLS may be formed by patterning the plug portion 25p, the first conductive layer 25a, the second conductive layer 25b, the third conductive layer 25c, the first capping layer 28a and the insulating material layers. The bit line structures BLS may extend in the Y direction, and may be spaced apart from each other in the X direction. The bit line structure BLS may include a bit line BL and a bit line capping layer 28 on the bit line BL. The patterned plug portion 25p, the patterned first conductive layer 25a, the patterned second conductive layer 25b and the patterned third conductive layer 25c may form the bit line BL. The patterned insulating material layers may be referred to as a second capping layer 28b and a third capping layer 28c, and the first capping layer 28a, the second capping layer 28b and the third capping layer 28c may form the bit line capping layer 28.

A spacer structure SP may be formed on either side surface of the bitline structure BLS. The spacer structure SP may include a first spacer SP1, a second spacer SP2, a third spacer SP3, and a fourth spacer SP4. The first spacer SP1 may be formed by conformally depositing an insulating material along a side surface of the bitline structure BLS and an internal wall of the contact hole H. The second spacer SP2 may be formed by depositing an insulating material on the first spacer SP1 to fill the contact hole H. The third spacer SP3 and the fourth spacer SP4 may be formed by forming an insulating material to cover side surfaces of the second spacer SP2 and the third spacer SP3 and etching the insulating material. The spacer structure SP may extend in the Y-direction along a side surface of the bitline structure BLS.

After the spacer structure SP is formed, a process of etching the buffer layer 21 may be performed to expose an upper surface of the second impurity region 9b of the active region 6a. A space between the bitline structures BLS may be referred to as a trench T. For example, the trench T may be defined by side surfaces of adjacent spacer structures SP opposing each other, and may extend in the Y-direction.

A first peripheral capping layer 128b, a second peripheral capping layer 128c, and a lower interlayer insulating layer 130 may be formed on the substrate 3 in the peripheral circuit area PA.

The first peripheral capping layer 128b may be conformally formed along the surfaces of the substrate 3, the second device isolation layer 6p, the peripheral gate structure GS_P and the peripheral gate spacer 129. The lower interlayer insulating layer 130 may be formed by forming an insulating material to cover the first peripheral capping layer 128b, and performing a planarization process to expose an upper surface of the first peripheral capping layer 128b. The second peripheral capping layer 128c may be formed to cover upper surfaces of the first peripheral capping layer 128b and the lower interlayer insulating layer 130. In an embodiment, the first peripheral capping layer 128b and the second peripheral capping layer 128c may be formed simultaneously with the second capping layer 28b and the third capping layer 28c of the bit line capping layer 28, respectively.

The peripheral gate structure GS_P, the peripheral gate spacer 129, the first peripheral capping layer 128b, the second peripheral capping layer 128c and the lower interlayer insulating layer 130 may form a peripheral structure PS. For example, the peripheral structure PS may be disposed on the substrate 3 in the peripheral circuit area PA and the interface area IA, and an upper surface of the peripheral structure PS may be disposed at the same level as an upper surface of the bit line structure BLS.

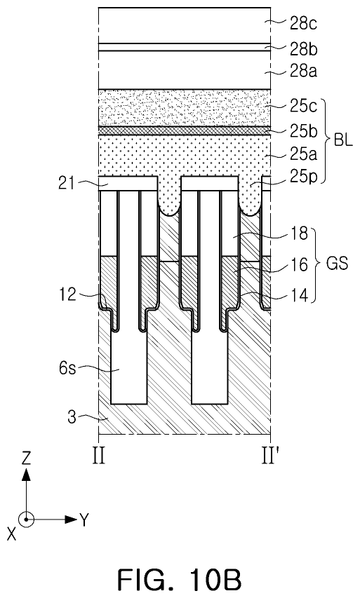

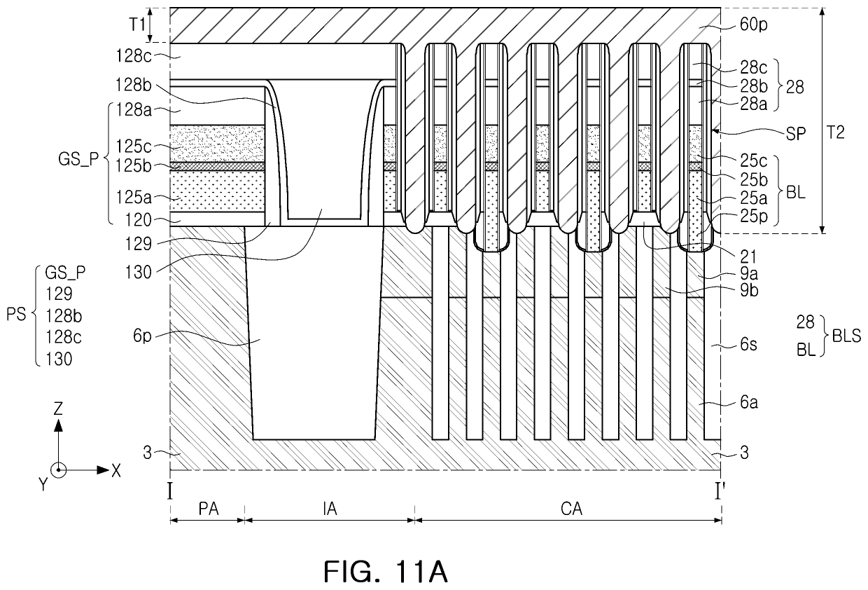

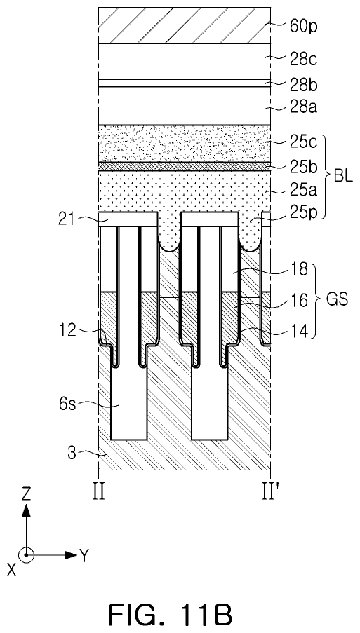

Referring to FIGS. 7A, 11A and 11B, the semiconductor material layer 60p covering the bit line structure BLS and the peripheral structure PS may be formed (S130). On the cell area CA, the semiconductor material layer 60p may fill the trenches T and cover the bit line structures BLS. The semiconductor material layer 60p may cover the peripheral structure PS on the peripheral circuit area PA and the interface area IA. In an embodiment, the semiconductor material layer 60p may be amorphous silicon.

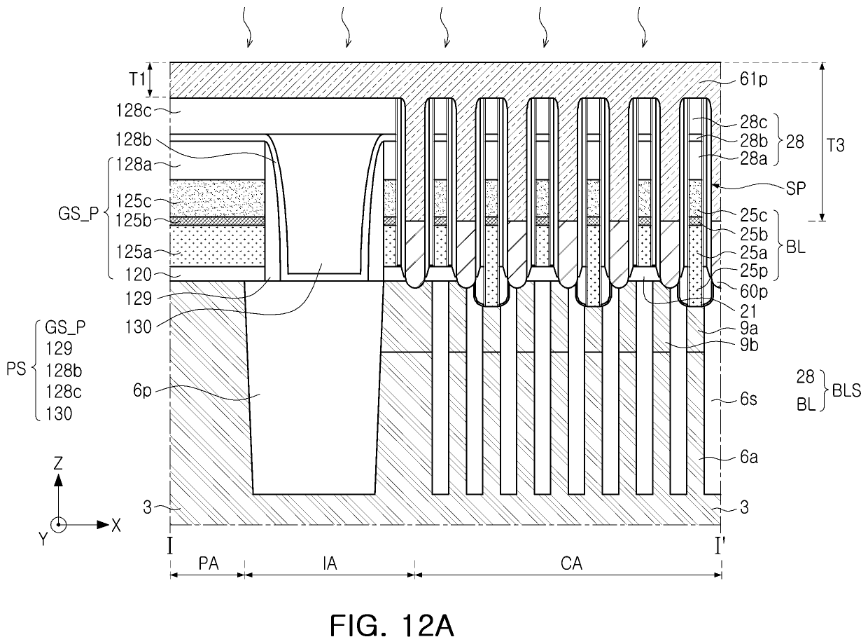

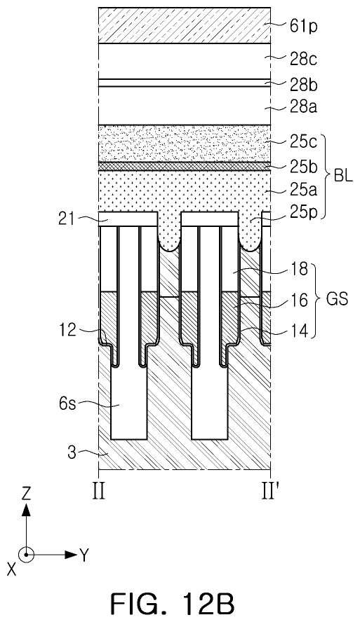

FIGS. 12A, 12B, 13 and 14 are diagrams for explaining a laser annealing process for laser annealing the semiconductor material layer 60p to form the contact plug 60 (S140). It may be possible to reduce electrical resistance of the contact plug 60 and prevent from forming voids inside the contact plug 60 by crystallizing the amorphous semiconductor material layer 60p by laser annealing. As described above, laser annealing the semiconductor material layer 60p to form the contact plug 60 (S140) may include crystallizing an upper portion of the semiconductor material layer by performing a primary laser annealing process to form a first preliminary crystal layer (S141), crystallizing a lower portion of the semiconductor material layer by performing secondary laser annealing process to form a second crystal layer (S142), and removing an upper portion of the first preliminary crystal layer to form a first crystal layer (S143).

Referring to FIGS. 7B, 12A and 12B, the first preliminary crystal layer 61p may be formed by crystallizing the upper portion of the semiconductor material layer 60p by performing the primary laser annealing process (S141). A portion of the semiconductor material layer 60p covering the bit line structure BLS and the peripheral structure PS may be crystallized by performing the primary laser annealing process. The primary laser annealing process comprises applying laser radiation via a laser beam to the semiconductor material layer 60p. For example, an upper surface of the first preliminary crystal layer 61p may be located at a higher level than the upper surface of the bit line structure BLS and an upper surface of the peripheral structure PS. The entire semiconductor material layer 60p may not be crystallized by the primary laser annealing process, and a portion of the semiconductor material layer 60p may remain in an amorphous state. For example, a lower surface of the first preliminary crystal layer 61p may be located at a higher level than the upper surface of the substrate 3. The portion of the semiconductor material layer 60p remaining in an amorphous state may be referred to as a lower portion of the semiconductor material layer 60p.

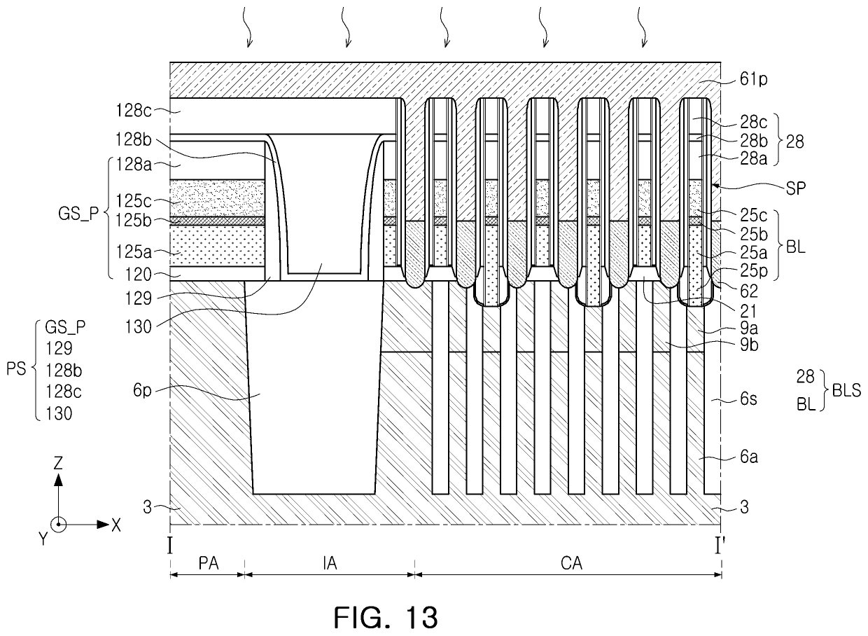

Referring to FIGS. 7B and 13, the second crystal layer 62 may be formed by crystallizing the lower portion of the semiconductor material layer 60p by performing the secondary laser annealing process (S142). The secondary laser annealing process comprises applying laser radiation via a laser beam to the first preliminary crystal layer 61p. The first preliminary crystal layer 61p crystallized by the primary laser annealing process may be more transparent to a laser beam than the semiconductor material layer 60p. Therefore, during the secondary laser annealing process, the laser beam may penetrate the first preliminary crystal layer 61p and reach the lower portion of the semiconductor material layer 60p, and the lower portion of the semiconductor material layer 60p may be crystallized. The entire lower portion of the semiconductor material layer 60p may be crystallized to form the second crystal layer 62. For example, the second crystal layer 62 may be in contact with the second impurity region 9b of the active region 6a.

In the primary laser annealing process and the secondary laser annealing process described with reference to FIGS. 12A and 13, the wavelength of the laser beam may be about 532 nm. In some embodiments, the laser beam may be visible light, and for example, a wavelength of the laser beam may be between about 400 nm and about 700 nm. In each of the primary laser annealing process and the secondary laser annealing process, an energy density (energy per unit area) of the laser beam may be about 75 mJ/cm² to 1200 mJ/cm². In an embodiment, an energy density of the laser beam used in the primary laser annealing process may be different from an energy density of the laser beam used in the secondary laser annealing process. For example, the energy density of the laser beam used in the primary laser annealing process may be greater than the energy density of the laser beam used in the secondary laser annealing process. In an embodiment, the laser beam may be a pulsed laser or a continuous wave (CW) laser.

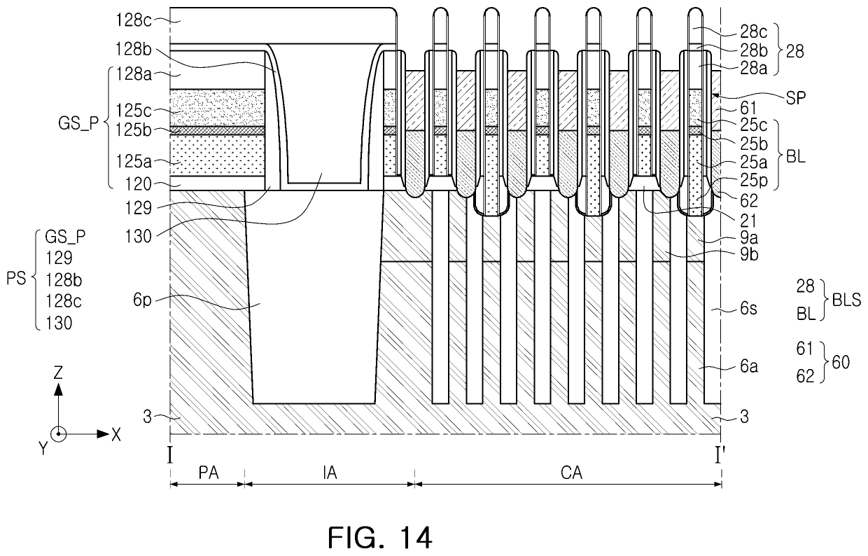

Referring to FIGS. 7B and 14, the first crystal layer 61 may be formed by removing an upper portion of the first preliminary crystal layer 61p (S143). For example, an etch-back process may be performed, and the upper portion of the first preliminary crystal layer 61p may be removed to expose the bit line structure BLS and the peripheral structure PS. The upper surface of the first crystal layer 61 may be located at a lower level than the upper surfaces of the bit line structures BLS and the upper surface of the peripheral structure PS. The bit line structures BLS may penetrate the first crystal layer 61. As such, portions of the first crystal layer 61 may be spaced apart from each other in the X direction with the bit line structures BLS interposed therebetween. The first crystal layer 61 and the second crystal layer 62 may form the contact plug 60. The contact plug 60 may be electrically connected to the active region 6a, for example, the second impurity region 9b.

In an embodiment, an interface may be observed between the first crystal layer 61 and the second crystal layer 62. For example, an average grain size of the first crystal layer 61 may be different from an average grain size of the second crystal layer 62.

Subsequently, a portion of the spacer structure SP may be etched by an etching process. For example, upper portions of the first spacer SP1, the third spacer SP3 and the fourth spacer SP4 may be partially removed.

In an embodiment, after the contact plug 60 is formed, a fence structure may be formed. The fence structure may be formed by removing a portion of the contact plug 60 and filling a space from which the portion of the contact plug 60 is removed with an insulating material. The fence structures may be formed to overlap the cell gate structure GS between the bitline structures BLS in a vertical direction. The fence structures may be disposed spaced apart from each other in the X-direction and the Y-direction. For example, the contact plugs 60 may be alternately disposed with the fence structures in the Y-direction between the bitline structures BLS. In example embodiments, the process of forming the fence structure may be performed prior to the process of forming the contact plug 60.

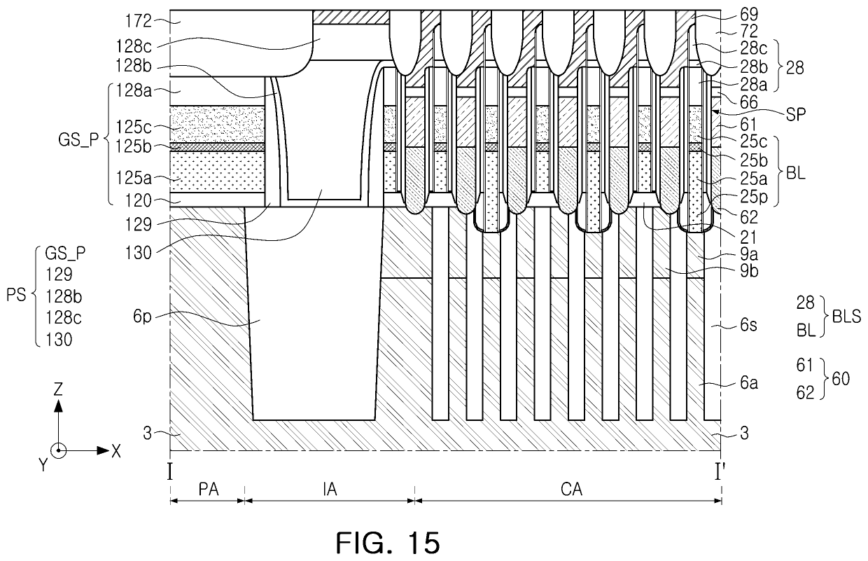

Referring to FIGS. 7A and 15, the landing pad 69 may be formed on the contact plug 60 (S150). The landing pad 69 may be formed by forming a conductive material to cover the bit line structure BLS and the spacer structure SP, and planarizing the conductive material. In an embodiment, the conductive material may be formed by a deposition process such as a chemical vaporization deposition (CVD) method, a physical vapor deposition (PVD) method, and an atomic layer deposition (ALD) method.

In an embodiment, a metal-semiconductor compound layer 66 may be formed between the contact plug 60 and the landing pad 69. The metal-semiconductor compound layer 66 may be formed by siliciding a portion of the contact plug 60.

A cell insulating pattern 72 may be formed between the landing pads 69 in the cell area CA. The cell insulating pattern 72 may be formed by forming an insulating material to cover the landing pad 69, and then etching the insulating material to expose the landing pad 69. An upper surface of the cell insulating pattern 72 may be coplanar with an upper surface of the landing pad 69. The cell insulating pattern 72 may electrically insulate the adjacent landing pads 69.

When forming the landing pad 69, the conductive material may also be formed on the peripheral circuit area CA and the interface area IA.

A peripheral insulating pattern 172 may be formed on the peripheral structure PS on the peripheral circuit area PA and the interface area IA. In an embodiment, the peripheral insulating pattern 172 may be formed simultaneously with the cell insulating pattern 72. For example, the peripheral insulating pattern 172 may be formed by forming an insulating material to cover the conductive material, and then etching the insulating material to expose the conductive material. When forming the peripheral insulating pattern 172, the conductive material on the peripheral circuit area PA and the interface area IA may be patterned to form a peripheral interconnection. An upper surface of the peripheral interconnection may be located at the same level as the upper surface of the landing pad 69.

Referring again to FIGS. 3 and 4, the capacitor structure 80 may be formed on the landing pad 69 in the cell area CA (S160).

An etch stop layer 75 may be formed to cover the landing pad 69 and the cell insulating pattern 72, and a lower electrode 82 may be formed to penetrate the etch stop layer 75 and be in contact with the landing pad 69. A capacitor dielectric layer 84 may be formed on the etch stop layer 75 and the lower electrode 82, and an upper electrode 86 may be formed on the capacitor dielectric layer 84. The lower electrode 82, the capacitor dielectric layer 84 and the upper electrode 86 may form the capacitor structure 80.

In the peripheral circuit area PA, an upper interlayer insulating layer 180 may be formed on the peripheral circuit pattern 172 to manufacture the semiconductor device 100. The upper interlayer insulating layer 180 may be disposed at the same level as the capacitor structure 80.

FIGS. 12A, 12B and 13 illustrate that the laser annealing process was performed twice, but aspects of the present inventive concept are not limited thereto. In some embodiments, the laser annealing process may be performed M times (M is greater than or equal to 2). Through the M laser annealing processes, the contact plug 60 may include M crystal layers. Average grain sizes of at least two of the M crystal layers may be different from each other. Extinction coefficients of at least two of the M crystal layers may be different from each other.

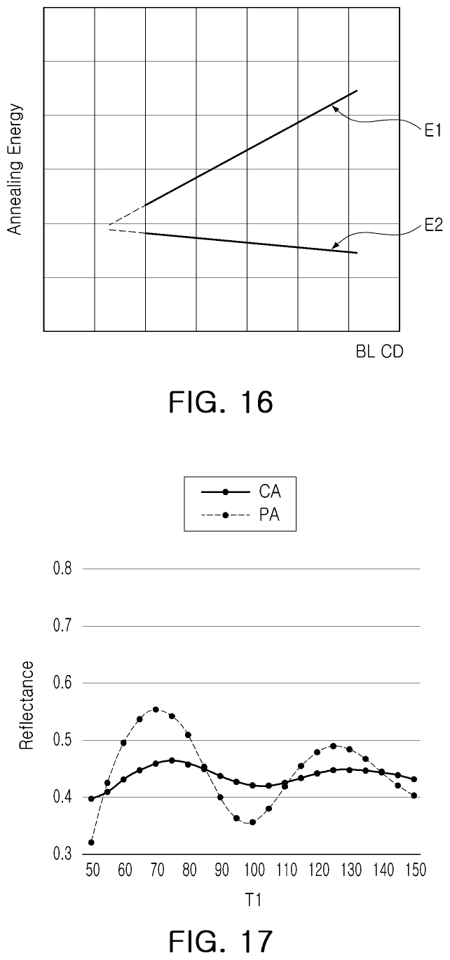

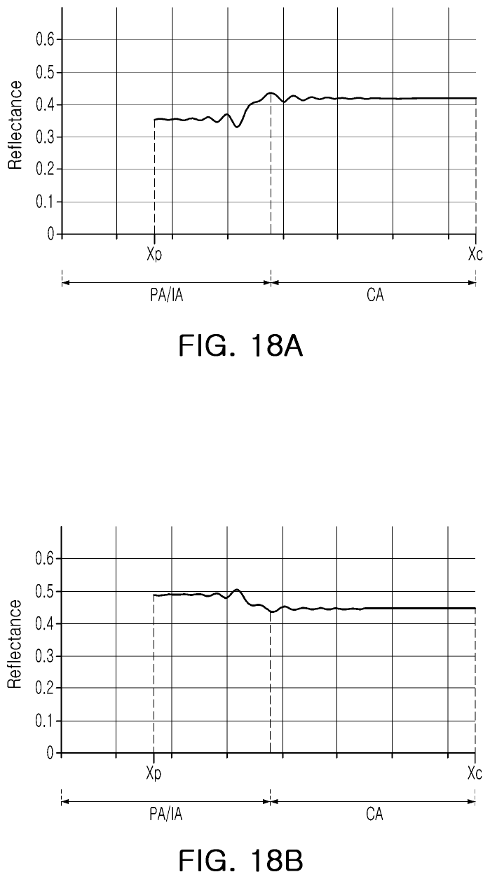

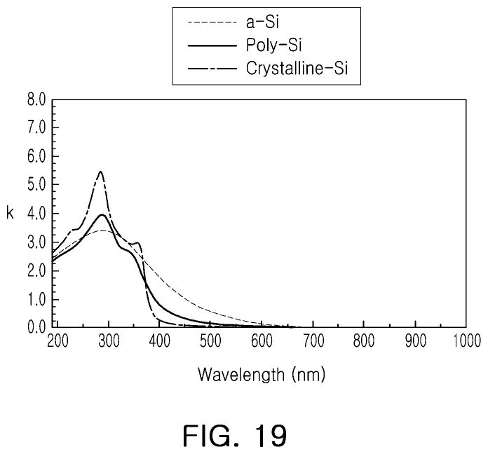

FIG. 16 illustrates a laser annealing energy as a function of a spacing between bit lines. For example, FIG. 16 illustrates upper and lower limits of the energy of usable laser beam as a function of the spacing CD between the bit lines BL during the laser annealing process. As illustrated in FIG. 16, as the spacing CD between the bit lines BL decreases, a width of the semiconductor material layer 60p between the bit lines BL narrows, so the difference between the upper limit and the lower limit of the energy of the usable laser beam may be reduced. That is, during the laser annealing process, an energy range of the usable laser beam may be reduced, thereby increasing the difficulty of the process. Hereinafter, with reference to FIGS. 17 to 22, an effect of the present inventive concept in increasing the energy range of the usable laser beam during the laser annealing process will be described. Specifically, FIGS. 17, 18A and 18B are diagrams for explaining the primary laser annealing process, and FIGS. 19 to 22 are diagrams for explaining the secondary laser annealing process.

FIG. 17 illustrates a reflectance as a function of a thickness of a semiconductor material layer.

Referring to FIGS. 11A and 17, the reflectance of the laser beam in the cell area CA and the peripheral circuit area PA may vary with a thickness T1 of a portion of the semiconductor material layer 60p covering the peripheral structure PS. For example, the lights reflected from the upper and lower surfaces of the semiconductor material layer 60p, respectively, destructively and constructively interfere with each other, so the reflectance may vary with the thickness T1 of the semiconductor material layer 60p. Here, the thickness T1 may mean a vertical distance from the upper surface of the peripheral structure PS, that is, an upper surface of the second peripheral capping layer 128c, to the upper surface of the semiconductor material layer 60p. Here, a reflectance of the laser beam in the peripheral circuit area PA may mean a reflectance of the entire structure including the peripheral structure PS and a portion of the semiconductor material layer 60p covering the peripheral structure PS. A reflectance of the laser beam in the cell area CA may mean a reflectance of the entire structure including the substrate 3, the bit line structure BLS and a portion of the semiconductor material layer 60p covering them.

FIG. 18A illustrates a reflectance of the laser beam in the cell area and the peripheral circuit area according to a comparative example. FIG. 18B illustrates a reflectance of the laser beam in the cell area and the peripheral circuit area according to an embodiment of the present inventive concept.

Referring to FIGS. 17 and 18A, in the comparative example, the thickness T1 of a portion of the semiconductor material layer 60p covering the peripheral structure PS may be about 100 nm. In this case, the reflectance in the peripheral circuit area PA may be less than the reflectance in the cell area CA. For example, the reflectance at the location Xp of the peripheral circuit area PA may be 0.35, and the reflectance at the location Xc of the cell area CA may be 0.42. Since the reflectance in the peripheral circuit area PA is less than the reflectance in the cell area CA, during the laser annealing process, a temperature of the semiconductor material layer 60p in the peripheral circuit area PA is greater than a temperature of the semiconductor material layer 60p in the cell area CA. Therefore, heat conduction may occur from the peripheral circuit area PA to the cell area CA. Accordingly, the cell area CA may be excessively heated, and voids may be generated between the first conductive layer 25a, the second conductive layer 25b and the third conductive layer 25c in the bit line BL by a Kirkendall effect.

Referring to FIGS. 17 and 18B, in an embodiment of the present inventive concept, the thickness T1 of a portion of the semiconductor material layer 60p covering the peripheral structure PS may be about 125 nm. In this case, the reflectance in the peripheral circuit area PA may be greater than the reflectance in the cell area CA. For example, the reflectance at the location Xp of the peripheral circuit area PA may be 0.49, and the reflectance at the location Xc of the cell area CA may be 0.44. Since the reflectance in the peripheral circuit area PA is greater than the reflectance in the cell area CA, during the laser annealing process, a temperature of the semiconductor material layer 60p in the peripheral circuit area PA may be less than a temperature of the semiconductor material layer 60p in the cell area CA. Therefore, heat conduction may not occur from the peripheral circuit area PA to the cell area CA, and the generation of voids in the bit line BL due to the Kirkendall effect may be prevented or reduced. The thickness T1 in FIG. 18B is exemplary, and aspects of the present inventive concept are not limited thereto. The thickness T1 may be any value such that the reflectance in the peripheral circuit area PA is greater than the reflectance in the cell area CA in FIG. 17.

In an embodiment, the thickness T1 of a portion of the semiconductor material layer 60p covering the peripheral structure PS may satisfy Equation 1 below:

$$( \frac{N}{2} + \frac{1}{8} + Δ ) \frac{λ}{{n}_{a - Si}} + δ \leq {t}_{a - Si} \leq ( \frac{N}{2} + \frac{3}{8} + Δ ) \frac{λ}{{n}_{a - Si}} + δ \qquad [ Equation 1 ]$$

In Equation 1, t_{a-Si} may be the thickness T1 of the semiconductor material layer 60p. λ may be a wavelength of the laser beam used in the laser annealing process, and n_{a-Si} may be a refractive index of the semiconductor material layer 60p. N may be one of 1, 2, or 3, and Δ and δ may be optical path correction factors. Δ may be −⅛ or more and ⅛ or less, and δ may be −4 nm or more and 4 nm or less. When the thickness T1 of the semiconductor material layer 60p satisfies Equation 1 above, the reflectance in the peripheral circuit area PA may be maximized and may be less than the reflectance in the cell area CA.

For example, in an embodiment where λ=532 nm, n_{a-Si}=4.8, Δ=−⅛ and δ=2 nm, when N=1, 57 nm≤t_{a-Si}≤85 nm, and when N=2, 113 nm≤t_{a-Si}≤141 nm, and when N=3, it may be 168 nm≤t_{a-Si}≤196 nm.

According to an embodiment of the present inventive concept, the reflectance of the peripheral circuit area PA can be increased and the temperature thereof can be reduced by adjusting the thickness T1 of the semiconductor material layer 60p without forming a reflective film on the peripheral circuit area PA. Therefore, compared to the case of forming a reflective film on the peripheral circuit area PA, the process can be simplified and the manufacturing cost of the semiconductor device can be reduced.

FIG. 19 illustrates an extinction coefficient as a function of a crystal state of silicon and a wavelength.

Referring to FIG. 19, at a wavelength of about 400 nm or more, an extinction coefficient of polycrystalline silicon (Poly-Si) may be less than that of amorphous silicon (a-Si) and greater than that of single crystalline silicon (Crystalline-Si). For example, when a wavelength of the laser beam is about 532 nm, the extinction coefficient of polycrystalline silicon (Poly-Si) may be about 0.060, and the extinction coefficient of amorphous silicon (a-Si) may be about 0.625. Accordingly, in the secondary laser annealing process of FIG. 12A, the first preliminary crystal layer 61p may be transparent to the laser beam, and the laser beam may penetrate the first preliminary crystal layer 61p and sufficiently reach the lower portion of the semiconductor material layer 60p.

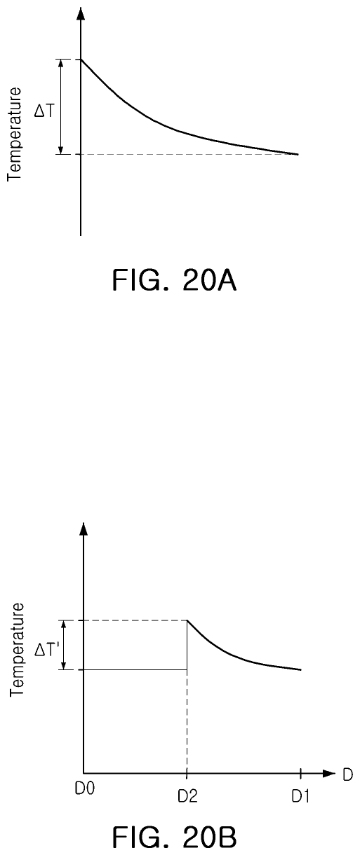

FIG. 20A illustrates a temperature of the semiconductor material layer on the cell area according to a comparative example. FIG. 20B illustrates a temperature of the semiconductor material layer on the cell area according to an embodiment. Specifically, FIG. 20A illustrates a temperature of the semiconductor material layer as a function of a depth D from the upper surface of the semiconductor material layer during the laser annealing process. FIG. 20B illustrates a temperature of the semiconductor material layer as a function of a depth D from the upper surface of the first preliminary crystal layer during the secondary laser annealing process after the primary laser annealing process.

Referring to FIG. 20A, in the comparative example, during the laser annealing process, the temperature may be maximum at the upper surface DO of the semiconductor material layer 60p, and the temperature may be minimum at a lower end D1 of the semiconductor material layer 60p. The temperature of the semiconductor material layer 60p may gradually decrease from the upper surface DO of the semiconductor material layer 60p to the lower end D1 of the semiconductor material layer 60p.

Referring to FIGS. 12A and 20B, in an embodiment of the present inventive concept, a temperature may be maximum at an interface D2 between the first preliminary crystal layer 61p and the remaining semiconductor material layer 60p during the secondary laser annealing process after the primary laser annealing process, and may be minimum at a lower end D1 of the semiconductor material layer 60p. That is, the temperature may be maximum at a lower surface of the first preliminary crystal layer 61p. As described above, since the first preliminary crystal layer 61p is transparent to the laser beam, a change in the temperature with a depth in the first preliminary crystal layer 61p is not great, and there may be no substantial change in the temperature. For example, the temperature at the lower surface of the first preliminary crystal layer 61p may be greater than or equal to the temperature at the upper surface of the first preliminary crystal layer 61p.

In order for crystallization to proceed at the lower end D1 of the semiconductor material layer 60p, the temperature of the lower end D1 of the semiconductor material layer 60p may be substantially the same in both the comparative example and the embodiment of the present inventive concept. However, since the temperature is maximum at the lower surface of the first preliminary crystal layer 61p in the embodiment of the present inventive concept, the maximum temperature value thereof may be less than the maximum temperature value in the comparative example. For example, a difference ΔT′ between the maximum temperature value and the minimum temperature value in the embodiment of the present inventive concept may be less than a difference ΔT between the maximum temperature value and the minimum temperature value in the comparative example. Therefore, according to the embodiment of the present inventive concept, since the difference ΔT′ between the maximum temperature value and the minimum temperature value is less, the upper limit of the energy of the usable laser beam can be lowered, as described with reference to FIG. 16. Accordingly, the energy of the laser beam used during the laser annealing process can be lowered and a less spacing CD between the bit lines BL can be implemented.

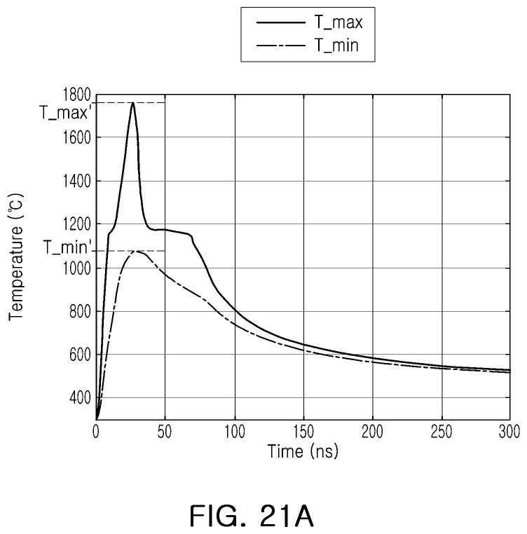

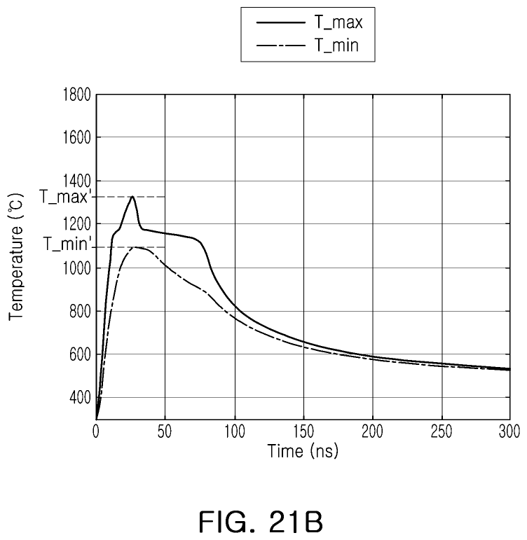

FIG. 21A illustrates a temperature of the semiconductor material layer on the cell area according to a comparative example. FIG. 21B illustrates a temperature of the semiconductor material layer on the cell area according to an embodiment of the present inventive concept. Specifically, FIG. 21A illustrates changes in maximum and minimum temperature values of the semiconductor material layer over time during the laser annealing process. FIG. 21B illustrates changes in maximum and minimum temperature values of the first preliminary crystal layer and the semiconductor material layer therebelow over time during the secondary laser annealing process after the primary laser annealing process.

Referring to FIG. 21A, the maximum temperature value T_max and the minimum temperature value T_min of the semiconductor material layer 60p during the laser annealing process in the comparative example may peak within a predetermined time range and then gradually decrease. As described with reference to FIG. 20A, the temperature of the semiconductor material layer 60p may be maximum at the upper surface DO and minimum at the lower end D1. In the comparative example, the peak value T_max′ of the maximum temperature and the peak value T_min′ of the minimum temperature may be 1762° C. and 1075° C., respectively, and the difference between the peak value T_max′ of the maximum temperature and the peak value T_min′ of the minimum temperature may be about 687° C.

Referring to FIG. 21B, the maximum temperature value T_max and the minimum temperature T_min of the first preliminary crystal layer 61p and the semiconductor material layer 60p therebelow during the secondary laser annealing process after the primary laser annealing process in the embodiment of the present inventive concept may peak within a predetermined time range and then gradually decrease. As described with reference to FIG. 20B, the temperature may be maximum at the lower surface of the first preliminary crystal layer 61p and minimum at the lower end D1 of the semiconductor material layer 60p. In the embodiment of the present inventive concept, the peak value T_max′ of the maximum temperature and the peak value T_min′ of the minimum temperature may be 1319° C. and 1092° C., respectively, and the difference between the peak value T_max′ of the maximum temperature and the peak value T_min′ of the minimum temperature may be about 237° C. Therefore, according to the embodiment of the present inventive concept, the difference between the peak value T_max′ of the maximum temperature and the peak value T_min′ of the minimum temperature can be reduced by about 65.5% compared to the comparative example. Accordingly, as described with reference to FIG. 20B, the energy of the laser beam used during the laser annealing process can be lowered and a less spacing CD between the bit lines BL can be implemented. Since the bit lines BL can be formed with the less spacing CD, a semiconductor device with a finer pattern can be implemented.

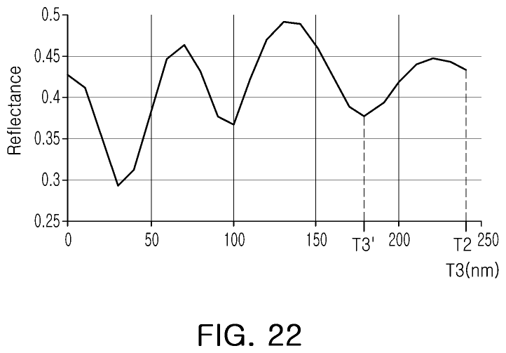

FIG. 22 illustrates a reflectance as a function of a thickness of the first preliminary crystal layer during the secondary laser annealing process. Specifically, FIG. 22 illustrates a simulation of a reflectance of a laser with a wavelength of 532 nm with respect to the entire structure including a substrate, an amorphous semiconductor material layer on the substrate and a first preliminary crystal layer on the semiconductor material layer, when the substrate, the semiconductor material layer and the first preliminary crystal layer are disposed.

Referring to FIGS. 12A and 22, the reflectance of the structure including the substrate 3, the semiconductor material layer 60p and the first preliminary crystal layer 61p may increase or decrease as a function of a thickness T3 of the first preliminary crystal layer 61p. For example, since the lights reflected from the lower and upper surfaces of the first preliminary crystal layer 61p, respectively, destructively and constructively interfere with each other, so the reflectance may vary with the thickness T3 of the first preliminary crystal layer 61p. As described above, the first preliminary crystal layer 61p that is crystalline is transparent to the laser beam, and therefore may have a low extinction coefficient. Therefore, the fact that the reflectance of the structure including the substrate 3, the semiconductor material layer 60p and the first preliminary crystal layer 61p has a minimum value means that the semiconductor material layer 60p disposed below the first preliminary crystal layer 61p may absorb more light. That is, by adjusting the thickness T3 of the first preliminary crystal layer 61p so that the reflectance is low, the semiconductor material layer 60p can be effectively heated and crystallized with the laser beam of less energy. In an embodiment, when the laser annealing process is performed twice, a thickness T3′ of the first preliminary crystal layer 61p, whose reflectance is minimized, may be about 70% to about 80% of the entire thickness T2 of the semiconductor material layer 60p illustrated in FIG. 11A.

In an embodiment, during the secondary laser annealing process, the reflectance of the laser beam in the peripheral circuit area PA may also be greater than that of the laser beam in the cell area CA.

For example, in FIG. 12A, the thickness T1 of a portion of the semiconductor material layer 60p covering the peripheral structure PS may satisfy Equation 2 below.

$$( \frac{N}{2} + \frac{1}{8} + Δ ) \frac{λ}{{n}_{c - Si}} + δ \leq {t}_{c - Si} \leq ( \frac{N}{2} + \frac{3}{8} + Δ ) \frac{λ}{{n}_{c - Si}} + δ \qquad [ Equation 2 ]$$

In Equation 2, t_{c-Si} may be the thickness T1 of the first preliminary crystal layer 61p covering the peripheral structure PS. 2 may be a wavelength of the laser beam used in the laser annealing process, and n_{c-Si} may be a refractive index of the first preliminary crystal layer 61p. N may be one of 1, 2, or 3, and Δ and δ may be optical path correction factors. Δ may be −⅛ or more and ⅛ or less, and δ may be −4 nm or more and 4 nm or less. When the thickness T1 of the first preliminary crystal layer 61p covering the peripheral structure PS satisfies Equation 2 above, the reflectance in the peripheral circuit area PA may be maximized and may be less than the reflectance in the cell area CA.

Therefore, during the secondary laser annealing process, the temperature in the peripheral circuit area PA may be less than that the temperature in the cell area CA, and heat conduction from the peripheral circuit area PA to the cell area CA may not occur.

In some embodiments, the laser annealing process may be performed M times (M is greater than or equal to 2). During at least one of the M laser annealing processes, the reflectance of the laser beam in the peripheral circuit area PA may be greater than the reflectance of the laser beam in the cell area CA. Energy densities of the laser beams used in the M laser annealing processes may be the same or different. For example, the energy densities of at least two laser beams among the laser beams used in the M laser annealing processes may be different from each other.

According to the embodiments of the present inventive concept, since the contact plug is formed by performing the multiple laser annealing processes, the energy used for the laser annealing processes can be reduced, and therefore, the semiconductor device can be implemented with a finer pattern.

Since the laser annealing process is performed without forming an anti-reflection film on the peripheral circuit area, the process can be simplified, and process costs can be reduced.

While example embodiments have been shown and described above, it will be apparent to those skilled in the art that modifications and variations could be made without departing from the scope of the present inventive concept as defined by the appended claims.

What is claimed is:

1. A method of manufacturing a semiconductor device, the method comprising:
forming a cell gate structure in a substrate comprising a cell area and a peripheral circuit area;
forming bit line structures on the cell area;
forming a peripheral structure comprising a peripheral gate structure on the peripheral circuit area;
forming a semiconductor material layer covering the bit line structures and the peripheral structure; and
forming a contact plug between the bit line structures by laser annealing the semiconductor material layer using a laser beam,
wherein the forming the contact plug comprises:
crystallizing an upper portion of the semiconductor material layer by performing a primary laser annealing process to form a first preliminary crystal layer;
crystallizing a lower portion of the semiconductor material layer by performing a secondary laser annealing process to form a second crystal layer; and
removing an upper portion of the first preliminary crystal layer to form a first crystal layer.

2. The method of claim 1, wherein a thickness (t_{a-Si}) of a portion of the semiconductor material layer covering the peripheral structure satisfies Equation 1:
$$( \frac{N}{2} + \frac{1}{8} + Δ ) \frac{λ}{{n}_{a - Si}} + δ \leq {t}_{a - Si} \leq ( \frac{N}{2} + \frac{3}{8} + Δ ) \frac{λ}{{n}_{a - Si}} + δ , \qquad ( Equation 1 )$$
where λ is a wavelength of the laser beam used for the primary laser annealing, n_{a-Si} is a refractive index of the semiconductor material layer, N is one of 1, 2, and 3, Δ and δ are optical path correction factors, Δ is −⅛ or more and ⅛ or less, and δ is −4 nm or more and 4 nm or less.

3. The method of claim 1, wherein during the primary laser annealing process, a reflectance of the laser beam in the peripheral circuit area is greater than a reflectance of the laser beam in the cell area.

4. The method of claim 1, wherein a thickness of the first preliminary crystal layer formed by the primary laser annealing process is about 70% to about 80% of an entire thickness of the semiconductor material layer.

5. The method of claim 1, wherein the second crystal layer is formed below the first preliminary crystal layer.

6. The method of claim 1, wherein a lower surface of the first crystal layer is located at a higher level than an upper surface of the substrate, and
a lower surface of the second crystal layer is in contact with the upper surface of the substrate.

7. The method of claim 1, wherein during the secondary laser annealing process, a temperature at a lower surface of the first preliminary crystal layer is greater than or equal to a temperature at an upper surface of the first preliminary crystal layer.

8. The method of claim 1, wherein during the secondary laser annealing process, a temperature at a lower surface of the first preliminary crystal layer is greater than a temperature at a lower end of the lower portion of the semiconductor material layer.

9. The method of claim 1, wherein during the secondary laser annealing process, among the first preliminary crystal layer and the lower portion of the semiconductor material layer, a temperature of a lower surface of the first preliminary crystal layer has a maximum value.

10. The method of claim 1, wherein during the secondary laser annealing process, a thickness (t_{c-Si}) of a portion of the first preliminary crystal layer covering the peripheral structure satisfies Equation 2:
$$( \frac{N}{2} + \frac{1}{8} + Δ ) \frac{λ}{{n}_{c - Si}} + δ \leq {t}_{c - Si} \leq ( \frac{N}{2} + \frac{3}{8} + Δ ) \frac{λ}{{n}_{c - Si}} + δ \qquad ( Equation 2 )$$
where λ is a wavelength of the laser beam used for the secondary laser annealing, n_{c-Si} is a refractive index of the first preliminary crystal layer, N is one of 1, 2, and 3, Δ and δ are optical path correction factors, Δ is −⅛ or more and ⅛ or less, and δ is −4 nm or more and 4 nm or less.

11. The method of claim 1, wherein a wavelength of the laser beam is about 532 nm.

12. The method of claim 1, wherein a wavelength of the laser beam is about 400 nm to about 700 nm.

13. The method of claim 1, wherein an energy density of the laser beam is about 75 mJ/cm² to about 1200 mJ/cm².

14. The method of claim 1, wherein an energy density of a first laser beam used for the primary laser annealing process is greater than an energy density of a second laser beam used for the secondary laser annealing process.

15. A method of manufacturing a semiconductor device, the method comprising:
forming a cell gate structure in a substrate comprising a cell area and a peripheral circuit area;
forming bit line structures on the cell area;
forming a peripheral structure comprising a peripheral gate structure on the peripheral circuit area;
forming a semiconductor material layer covering the bit line structures and the peripheral structure; and
forming a contact plug between the bit line structures by laser annealing the semiconductor material layer using a laser beam,
wherein the forming the contact plug comprises crystallizing the semiconductor material layer by M laser annealing processes, where M is 2 or more, and
at least two of respective laser beams used for the M laser annealing processes have different energy densities to each other.

16. The method of claim 15, wherein the contact plug comprises M crystal layers, and
at least two of the M crystal layers have different grain sizes from each other.

17. A method of manufacturing a semiconductor device, the method comprising:
forming a cell gate structure in a substrate comprising a cell area and a peripheral circuit area, the cell gate structure extending in a first horizontal direction;
forming bit line structures extending in a second horizontal direction, intersecting the first horizontal direction, and disposing on the substrate on the cell area;
forming trenches between the bit line structures so that active regions within the substrate are exposed,
forming a peripheral structure comprising a peripheral gate structure on the peripheral circuit area;
forming a semiconductor material layer covering the bit line structures and the peripheral structure; and
forming contact plugs between the bit line structures by laser annealing the semiconductor material layer using a laser beam,
wherein the contact plugs are disposed in the trenches and in contact with the active regions;
wherein the forming the contact plug comprises:
crystallizing an upper portion of the semiconductor material layer by performing a primary laser annealing process to form a first preliminary crystal layer;
crystallizing a lower portion of the semiconductor material layer by performing a secondary laser annealing process to form a second crystal layer; and
removing an upper portion of the first preliminary crystal layer to form a first crystal layer.

18. The method of claim 17, wherein the grain size of the first crystal layer is greater than the grain size of the second crystal layer, and
an extinction coefficient of the first crystal layer is less than an extinction coefficient of the second crystal layer.

19. The method of claim 17, further comprising:
forming landing pads on the contact plugs; and
forming a capacitor structure including lower electrodes electrically connected to the landing pads.

20. The method of claim 17, wherein a height of the first crystal layer is greater than a height of the second crystal layer.
